(19) United States
(12) Patent Application Publication
(10) Pub. No.: US 2025/0306454 A1
(43) Pub. Date: Oct. 2, 2025

(54) APPARATUS AND METHOD FOR CORRECTING MASK FOR FABRICATING SEMICONDUCTOR DEVICE

(71) Applicant: SAMSUNG ELECTRONICS CO., LTD., Suwon-si (KR)

(72) Inventors: Jeeyong Lee, Suwon-si (KR); Useong Kim, Suwon-si (KR); Sooyong Lee, Suwon-si (KR); Kyoil Koo, Suwon-si (KR); Seongtae Jeong, Suwon-si (KR); Hyungjoon Cho, Suwon-si (KR)

(21) Appl. No.: 19/030,049

(22) Filed: Jan. 17, 2025

(30) Foreign Application Priority Data
Mar. 26, 2024 (KR) 10-2024-0041436

(51) Int. Cl. G03F 1/84; G03F 7/00

(52) U.S. Cl. CPC G03F 1/84; G03F 7/70441; G03F 7/70504

(57) ABSTRACT

A method is presented for correcting a photomask includes receiving a target design layout of a semiconductor device. The method includes inferring, by a processor, a mask bias by inputting into a first machine learning model an optical feature value, a geometrical feature value, and a resist feature value of a mask layout based on the target design layout. The processor generates a predicted pattern by incorporating the mask bias in the mask layout, and by comparing the predicted pattern with the target design layout the processor then corrects the mask layout based on a result of the comparison between the predicted pattern and the target design layout.

### CROSS-REFERENCE TO RELATED APPLICATION

This application claims priority under 35 U.S.C. § 119 to Korean Patent Application No. 10-2024-0041436 filed on Mar. 26, 2024, in the Korean Intellectual Property Office, the disclosures of which are incorporated by reference herein in their entireties.

### BACKGROUND

Implementations of the present disclosure described herein relate to an apparatus and a method for correcting a mask for fabricating a semiconductor device.

A semiconductor device (for example, a semiconductor chip) has patterns formed through a photolithography process and an etching process. A pattern layout is designed for a circuit pattern of a semiconductor chip, which is to be formed on a wafer, and a designed pattern layout is transferred onto the wafer by using a mask through the photolithography process. The circuit pattern transferred onto the wafer may be made different than the circuit pattern designed, due to an optical proximity effect in the photolithography process or the loading effect in the etching process. An optical proximity correction (OPC) operation or a process proximity correction (PPC) operation may be performed such that the circuit pattern on the mask is exactly transferred onto the wafer.

### SUMMARY

Implementations of the present disclosure provide an apparatus and a device for correcting a mask for fabricating a semiconductor device such that a circuit pattern is exactly transferred to a wafer.

According to implementations of the present disclosure, a method for correcting a photomask includes receiving a target design layout of a semiconductor device, inferring, by a processor, a mask bias by inputting an optical feature value, a geometrical feature value, and a resist feature value of a mask layout based on the target design layout, into a first machine learning model, generating, by the processor, a predicted pattern by incorporating the mask bias in the mask layout, comparing, by the processor, the predicted pattern with the target design layout, and correcting, by the processor, the mask layout based on a result of the comparison between the predicted pattern and the target design layout.

According to implementations of the present disclosure, a method for generating a photomask correction model may include receiving a mask layout of a semiconductor device, receiving measurement data of a wafer fabricated using a mask based on the mask layout, and training, by a processor, a first machine learning model using training data obtained by labeling an optical feature value, a geometrical feature value, and a resist feature value of the mask layout with a mask bias based on the measurement data.

According to implementations of the present disclosure, a method for determining a photomask correction amount, may include receiving an edge placement error corresponding to each of a plurality of evaluation points on a wafer fabricated using a mask based on a mask layout of a semiconductor device, inferring a correlation of edge placement error between the plurality of evaluation points using a machine learning model, and determining the photomask correction amount of the mask layout, based on the correlation of the edge placement error and an edge placement error corresponding to each of the plurality of evaluation points. The machine learning model is trained using data obtained by labeling a feature vector including at least one of an optical feature value, a geometrical feature value, or a resist feature value corresponding to each of the plurality of evaluation points, and relative coordinates between the plurality of evaluation points, with an edge placement error variation degree of one evaluation point for movement of another evaluation point of the plurality of evaluation points.

### BRIEF DESCRIPTION OF THE FIGURES

The above and other objects and features of the present disclosure will become apparent by describing in detail implementations thereof with reference to the accompanying drawings.

FIG. 1 is a block diagram illustrating an apparatus for correcting a mask according to some implementations of the present disclosure.

FIG. 2 is a block diagram illustrating components of the apparatus for correcting the mask of FIG. 1.

FIG. 3 is a view illustrating a circuit pattern of a mask and a circuit pattern on a wafer, after a photolithography process and an etching process are performed.

FIG. 4 is a view conceptually illustrating a method for correcting a mask by the apparatus for correcting the mask of FIG. 1.

FIG. 5 is a flowchart illustrating a method for correcting a mask, which is performed in the apparatus for correcting the mask of FIG. 1.

FIG. 6 is a view illustrating a first machine learning model for inferring a mask bias.

FIG. 7 is a view illustrating a training data of a first machine learning model.

FIG. 8 is a view illustrating a first machine learning model according to some implementations.

FIGS. 9A to 9D are views illustrating optical feature vectors of feature vectors.

FIGS. 10A to 10B are views illustrating a resist feature vector of feature vectors.

FIG. 11 is a view illustrating a geometrical feature vector of a feature vector.

FIGS. 12A and 12B are views to describe mask correction of a Manhattan mask and a curvilinear mask.

FIG. 13 is a flowchart illustrating a method for correcting a mask, based on EPE correlation.

FIG. 14 is a view illustrating a second machine learning model for inferring a mask correction amount.

FIG. 15 is a view illustrating a method for determining a mask correction amount.

FIG. 16A is a view illustrating an initial mask layout.

FIG. 16B is a view illustrating a mask layout in the process for correcting the initial mask layout.

FIG. 16C is a view illustrating a mask layout when the correction of the initial mask layout is completed.

### DETAILED DESCRIPTION

Hereinafter, implementations of the present disclosure will be described clearly and in detail to the extent that an ordinary person skilled in the art to which the present disclosure pertains easily reproduces the present disclosure.

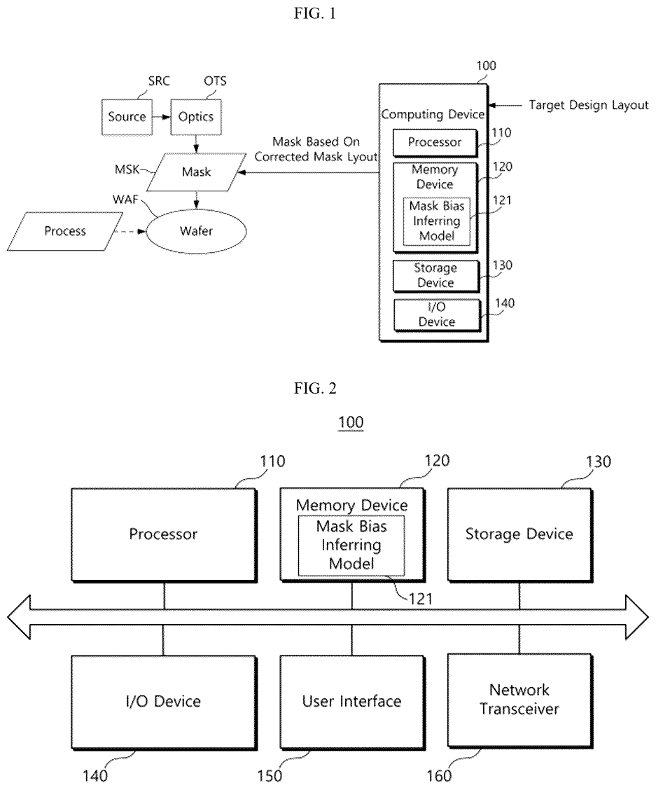

FIG. 1 is a block diagram illustrating an apparatus for correcting a mask for fabricating a semiconductor device according to some implementations of the present disclosure. The apparatus (hereinafter, referred to as a “mask correcting device) for correcting the mask may be implemented by a computing device 100. The correction of the mask according to the present disclosure will be described with the same meaning as that of the correction of a mask layout for forming the mask.

The computing device 100 may include at least one processor 110, a memory device 120, a storage device 130, and an input/output device 140. The processor 110, the memory device 120, the storage device 130, and the input/output device 140 may make communication with each other using a system bus.

The computing device 100 may operate as a dedicated device to design a semiconductor device, and to perform the optical proximity correction (OPC) operation and/or the process proximity correction (PPC) operation.

The computing device 100 may receive a target design layout of the semiconductor device and may form a final mask layout obtained by correcting a mask layout corresponding to the target design layout through a mask tape out (MTO) process. An electron-beam (e-beam) writer may be controlled to form a pattern in a blank mask based on the final mask layout, thereby forming a mask MSK. The mask MSK formed based on the final mask layout may be used for a photolithography process of the semiconductor device. The electron-beam writer may be a multi-beam mask writer (MBMW), or a variable shape beam mask writer (VSBMW). In addition, the mask MSK may be used to form a mask pattern through a layer exposure process. The mask MSK based on the final mask layout may include at least one of a rectilinear pattern and/or a curvilinear pattern.

The mask MSK may be used as a photolithography mask. Light emitted from a light source SRC may illuminate the mask MSK through an optical system OTS, and an optical pattern formed through the mask MSK may be transferred onto a wafer WAF though the optical system OTS. A resist on the wafer WAF may be exposed through the optical pattern transferred onto the wafer WAF. The exposed resist is developed, and the resist patterned onto the wafer WAF is formed. Processes such as a deposition process, a doping process, and/or an etching process may be performed based on the patterned resist, and structures related to the circuit pattern may be formed onto the wafer WAF.

According to some implementations of the present disclosure, the computing device 100 may infer a mask bias using a mask bias inferring model 121 which is a learning model based on machine learning. The computing device 100 may load the mask bias inferring model 121, which is stored in the storage device 130, onto the memory device 120, and may infer a mask bias by inputting at least one feature vector of the mask layout based on the target design layout, which is received, into the mask bias inferring model 121. According to some implementations, the computing device 100 may generate the mask layout based on the target design layout received or may receive the mask layout corresponding to the target design layout, together with the target design layout. According to some implementations, the target layout of the semiconductor device may be based on at least one of an after develop inspection (ADI) design layout or an after cleaning inspection (ACI) design layout. According to some implementations, the mask layout may be formed by performing an OPC operation for the target design layout. According to some implementations, the mask layout may be formed by performing the OPC operation and the PPC operation based on another process, with respect to the target design layout.

The computing device 100 may input, to the mask bias inferring model 121, an optical feature vector, a geometrical feature vector, and a resist feature vector of the mask layout, and may infer a mask bias. According to some implementations, the computing device 100 may input, to one mask bias inferring model 121, the optical feature vector, the geometrical feature vector, and the resist feature vector of the mask layout. In the specification, inputting the feature vector into the mask bias inferring model 121 may mean inputting a numerical value corresponding to the feature vector into the mask bias inferring model 121. The numerical value corresponding to the feature vector may be called a feature vector value. Accordingly, the mask bias may be rapidly inferred, as compared to a related art of directly comparing, with the target layout, a predicted pattern image obtained by applying an optical model and/or a resist model to a mask image based on the target layout. In addition, according to the related art, the predicted pattern image is generated based on an image, thereby increasing a computation load and making it difficult to consider geometric information in a wider range around an individual pattern. However, according to some implementations of the present disclosure, the computing device 100 may infer a mask bias by inputting the optical feature vector, the geometrical feature vector, and the resist feature vector into the mask bias inferring model 121 in the form of a numeric value, thereby inferring the mask bias rapidly and accurately while considering the wider range around the individual pattern. For example, one mask bias inferring model 121 may infer the mask bias by considering skews caused in the photolithography process and the etching process in the semiconductor fabricating process.

The computing device 100 may correct the mask layout by using the inferred mask bias and may generate the final mask layout through a mask tape out (MTO). The mask bias inferring model 121, which is a learning model based on machine learning, may infer the mask bias by considering the optical feature vector, the geometrical feature vector, and the resist feature vector, thereby improving the accuracy in inferring the mask bias. Accordingly, the mask may be corrected, such that the intended circuit pattern is exactly generated onto the wafer.

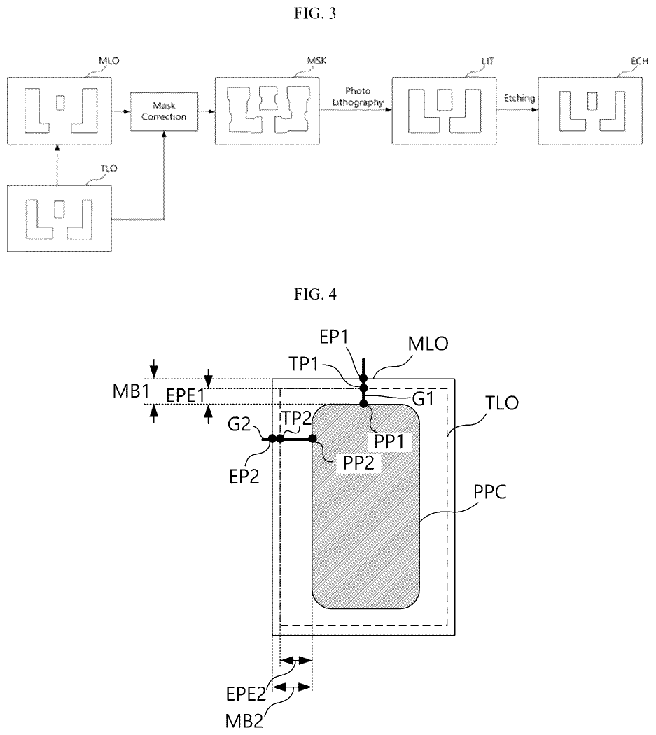

FIG. 2 is a block diagram illustrating components of the mask correcting device 100 of FIG. 1.

The computing device 100 may include a processor 110, a memory device 120, a storage device 130, an input/output device 140, a user interface 150, and a network transceiver 160.

A code loaded into the memory device 120 and temporarily stored in the memory device 120 may be an instruction to control the operation of the processor 110. According to some implementations, the memory device 120 may be a memory device (processing-in-memory (PIM)) to perform a processing function.

According to some implementations of the present disclosure, the processor 110 may load the mask bias inferring model 121 from the storage device 130. The processor 110 may temporarily store a target design layout, which is received online or offline through the network transceiver 160, in the memory device 120. The processor 110 may calculate feature vector values corresponding to a plurality of evaluation points (EPs) of a mask layout based on the target design layout. The mask bias may be inferred by inputting the feature vectors into the mask bias inferring model 121. The processor 110 may generate a predicted pattern contour based on the inferred mask bias and may correct the mask layout based on the comparison result between the predicted pattern contour and the target design layout. The processor 110 may repeatedly infer the mask bias, generate the predicted pattern contour, compare between the predicted pattern contour and the target design layout, and correct the mask layout, until reaching a preset criterion.

The processor 110 may include a learning processor based on artificial intelligence (AI) to accelerate the computation of the machine learning. The learning processor may be a processor including a graphic processing unit (GPU), a tensor processor, a neural processing unit (NPU), and a digital signal processor (DSP). In this specification, the machine learning may be interpreted as a concept including deep learning.

The processor 110 may apply a weighting parameter of the mask bias inferring model 121 to the feature vector, based on machine learning.

For example, when the mask bias inferring model 121 is based on a neural network, the processor 110 may input a value, which is output from nodes at each layer of the mask bias inferring model 121, into nodes at a next layer. For example, when the mask bias inferring model 121 is based on the neural network, the processor 110 may input a feature vector to each node at an input layer in the form of an input vector. The mask bias inferring model 121 may output the mask bias, based on a network structure and a weight value of the neural network.

Alternatively, when the mask bias inferring model 121 is based on a linear regression model, the processor 110 may perform a computation for parameters and a feature vector value constituting the linear regression model.

Alternatively, when the mask bias inferring model 121 is based on a non-linear model, the processor 110 may perform a computation for parameters and a feature vector value constituting the non-linear model or may perform inference based on the feature vector value. For example, when the mask bias inferring model 121 is based on, for example, a decision tree or a random forest, which is the non-linear model, the processor 110 may input the feature vector to each node at the root, in the form of an input vector. The mask bias inferring model 121 may infer the mask bias based on the tree structure branching based on the decision reference at each node of the tree or may output a value for supplementing the mask bias inferred trough another learning model.

The memory device 120 may temporarily store codes for the operation of the computing device 100, data for the operation of the processor 110, parameters of the mask bias inferring model 121, and an intermediate computation result of the mask bias inferring model 121.

The storage device 130 may store the trained mask bias inferring model 121. The storage device 130 may include a computer-readable storage medium. The storage medium includes all types of recording media to store computer-readable data. The storage medium may include at least any one of a hard disk drive (HDD), a solid state disk (SSD), a silicon disk drive (SDD), a ROM, a RAM, a CD-ROM, a magnetic tape, a floppy disk, or an optical data storage device.

According to some implementations, the storage device 130 may store a plurality of mask bias inferring models 121 mutually differently trained based on the optical characteristics, such as the structure of the optical system and/or the type of a light source. In addition, the storage device 130 may store a plurality of mask bias inferring models 121 mutually differently trained based on a resist characteristic, such as the recipe of the resist. Alternatively, the storage device 130 may store a plurality of mask bias inferring models 121 mutually differently trained, based on the type (an ACI design layout or an ADI design layout) of the target design layout. In other words, a plurality of learning models may be stored in the storage device 130, depending on characteristics of the training data. The computing device 100 may use the mask bias inferring models 121 mutually different, based on meta data corresponding to the target layout design.

The mask bias inferring model 121 may be a learning model based on deep-learning, or machine-learning, which includes a plurality of layers including a neural network.

The neural network of the mask bias inferring model 121 may include at least any one of a convolution neural network (CNN), a region with convolution neural network (R-CNN), a region proposal network (RPN), a recurrent neural network (RNN), a long short-term memory (LSTM) network, a stacking-based deep neural network (s-DNN), a state-space dynamic neural network (S-SDNN), a deep belief network (DBN), or a restricted boltzmann machine (RBM), without excluding other neural network structures.

The mask bias inferring model 121, which is a learning model based on machine-learning, may be a learning model based on a decision tree, a random forest, k-nearest neighbors (N-NN), a logistics regression, an association rule, a genetic algorithm, inductive learning, support vector machine (SVM), cluster analysis, a Bayesian network, reinforcement learning, or a regression model, without excluding learning models having other structures.

The mask bias inferring model 121 may be implemented in hardware, software, or a combination of hardware and software. When a portion or the entire portion of the mask bias inferring model 121 is implemented in software, at least one instruction constituting the learning model may be stored in the storage device 130.

The user interface 150 may include a device, such as a display device, a mouse device, or a keyboard device, to receive an input from a user or to provide an output from the computing device 100.

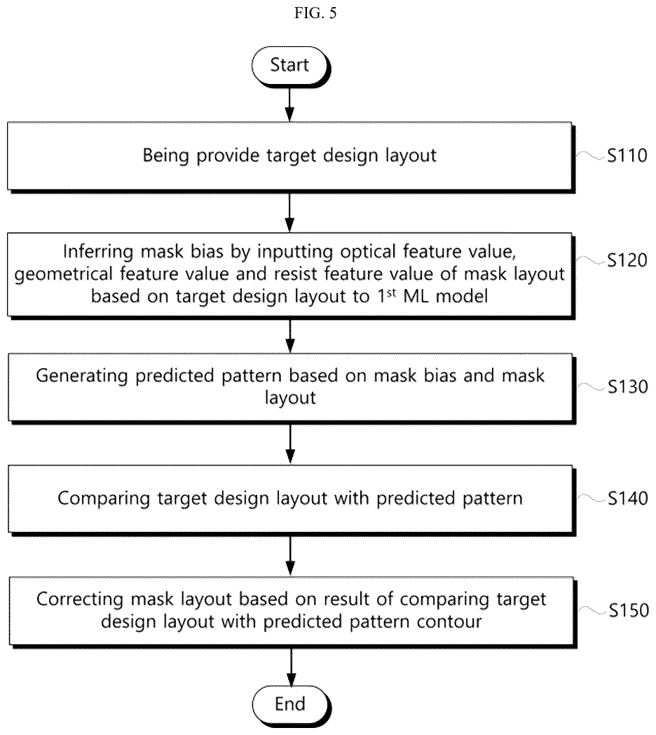

FIG. 3 is a view illustrating a circuit pattern of a target design layout TLO, a circuit pattern of a mask layout MLO, a circuit pattern of a mask MSK corrected by the computing device 100 according to some implementations of the present disclosure, a circuit pattern on a wafer LIT after a photolithography process, and a circuit pattern on a wafer ECH obtained after an etching process. The circuit pattern may be a circuit pattern on a layout or a portion of a circuit pattern on a wafer LIT. The circuit pattern on the wafer LIT after the photolithography process may be a circuit pattern at a mask layer of a wafer. The mask MSK of FIG. 3 may correspond to a mask MSK processed through the MTO by the computing device 100 described with reference to FIG. 1. Hereinafter, the change in the circuit pattern will be described with reference to FIGS. 1 and 3.

Various circuit patterns may be formed on the wafer through various semiconductor processes. According to some implementations, the skew caused in a photolithography process, an etching process, a deposition process, and a polishing process using a mask formed based on a mask layout having the shape corresponding to patterns, may make differences between the shapes of the patterns of the mask layout and the shapes of real patterns formed on the wafer through the semiconductor process. Accordingly, to form the intended circuit pattern on the wafer, the mask layout should be designed based on the skew caused in the semiconductor process.

Referring to FIG. 3, the mask layout designed with patterns to be formed may be provided to the computing device 100 or the computing device 100 may generate the mask layout MLO based on a target design layout TLO of the semiconductor device. According to some implementations, the mask layout MLO may be a mask layout obtained after the OPC operation. The mask layout MLO may have a graphic data form used in electronic design automation (EDA) software. For example, the mask layout MLO may be provided in the form of a data format, such as a graphic design system (GDS) or OASIS. According to some implementations, the computing device 100 may verify the mask layout MLO. For example, the computing device 100 may perform a design rule check (DRC) and/or a layout versus schematic (LVS) with respect to the mask layout MLO.

According to some implementations of the present disclosure, the computing device 100 may produce a corrected mask layout MSK based on the mask layout MLO and the target design layout TLO.

The computing device 100 may infer the skew caused in the circuit pattern formed on the wafer, through the mask bias inferring model 121 based on the machine learning, when using the mask produced based on the mask layout MLO. The computing device 100 may produce the corrected mask layout MSK produced by correcting the mask layout MLO based on the inferred skew. The shape of the corrected mask layout MSK may be changed from the shape of the mask layout MLO, based on the skew in the process for fabricating the semiconductor device. For example, the corrected mask layout MSK may have the shape changed from the shape of the mask layout MLO based on the skew in the photolithography process and/or the etching process. It may be recognized that the corrected mask layout MSK of FIG. 3 has a serif pattern or a hammer pattern additionally provided at corners of patterns and the line width of the pattern is changed, as compared to that of the mask layout MLO. In other words, the pattern of the corrected mask layout MSK may have the shape and/or the size different from that of at least a portion of the pattern of the mask layout MLO.

The photolithography process may be performed with respect to the wafer using the mask produced based on the corrected mask layout MSK. For example, the photolithography process may be performed by irradiating light through patterns of the mask produced based on the corrected mask layout MSK or by irradiating light through a region except for the patterns. The pattern formed at the mask layer of the wafer through the optical proximity effect produced in the photolithography process may have the shape and/or the size at least partially different from that of the pattern of the corrected mask layout MSK. Thereafter, processes for fabricating the semiconductor device may be performed using the mask layer and the circuit pattern may be formed on the wafer. For example, the semiconductor device and/or upper layers on the semiconductor substrate may be etched through the etching process, in a region which is exposed by the patterns included in the mask layer of the wafer LIT subject to the photolithography process. The circuit pattern formed on the wafer ECH obtained after the etching process may have the shape and/or the size at least partially different from that of the pattern of the corrected mask layout MSK. The intended circuit pattern may be exactly formed on the wafer using the mask produced based on the corrected mask layout MSK.

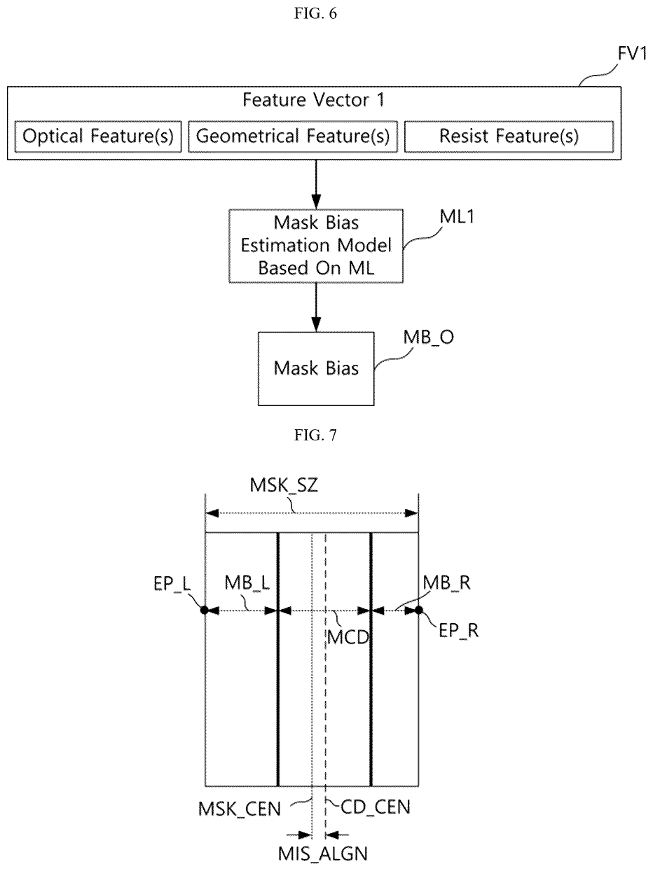

FIG. 4 is a view conceptually illustrating a method for correcting a mask layout by a computing device performing mask correction. The computing device may correspond to the computing device 100 of FIG. 1.

According to some implementations of the present disclosure, the computing device 100 may correct an initial mask layout at least partially to generate the final mask layout. The computing device 100 may infer a mask bias from the mask layout during the mask correction and may generate a predicted pattern based on the inferred mask bias and the mask layout. The computing device 100 may determine whether to perform the mask correction and may determine a mask correction amount, by comparing the predicted pattern with the target design layout. In this specification, the mask layout and/or the target design layout may refer to a circuit pattern, which is included in the mask layout, and/or the target design layout. For example, comparing the target design layout with the predicted pattern may be comparing the circuit pattern, which is included in the target design layout, with the predicted pattern. The predicted pattern may be a circuit pattern, which is predicted, expressed in the form of a contour.

Referring to FIG. 4, the computing device 100 may set a plurality of evaluation points (EPs) at some positions of the circuit pattern included in the mask layout during the mask correction, before the final mask layout is generated. For example, FIG. 4 illustrates two evaluation points EP1 and EP2 set in a circuit pattern included in the mask layout MLO during the mask correction. Actually, although many more evaluation points (EPs) may be set in the circuit pattern, the following description will be made with reference to FIG. 4 on the assumption that the two evaluation points EP1 and EP2 are set for the convenience of explanation.

The computing device 100 may set gauges G1 and G2 corresponding to the evaluation points EP1 and EP2. When the mask layout is a Manhattan mask layout having a rectilinear circuit pattern, the gauges G1 and G2 may be formed in a direction perpendicular to each edge of a circuit pattern having the evaluation points EP1 and EP2. When the mask layout is a curvilinear mask layout having a curvilinear pattern, the gauges G1 and G2 may be formed in a direction normal to each edge of a circuit pattern having the evaluation points EP1 and EP2. Points, which correspond to the evaluation points EP1 and EP2, along the gauges G1 and G2 in the circuit pattern of the target design layout TLO may be set as the target points TP1 and TP2.

The computing device 100 may input feature vectors corresponding to the evaluation points EP1 and EP2 into the mask bias inferring model 121 and infer mask biases MB1 and MB2 corresponding to the evaluation points EP1 and EP2.

The computing device 100 may generate a predicted pattern PPC, based on the mask biases MB1 and MB2 and the circuit pattern included in the mask layout MLO. For example, the predicted pattern PPC may be generated, based on predicted points PP1 and PP2 of the predicted pattern PPC. Each of the predicted points PP1 and PP2 may be spaced apart from a relevant one of the evaluation points EP1 and EP2 of the circuit pattern, which is included in the mask layout MLO, respectively, by a relevant one of the mask biases MB1 and MB2.

The computing device 100 may compare between the predicted pattern PPC and the circuit pattern of the target design layout TLO. When differences EPE1 and EPE2 are beyond a specific reference, the mask correction may be determined. The difference between the predicted pattern PPC and the circuit pattern of the target design layout TLO may be predicted edge placement error (EPE). The computing device 100 may determine a mask correction amount, based on the predicted EPEs EPE1 and EPE2.

The computing device 100 may iterate inferring the mask biases MB1 and MB2, generating the predicted pattern PPC, comparing between the predicted pattern PPC and the circuit pattern for the target design layout TLO, and determining whether to correct the mask, until the predicted EPEs EPE1 and EPE2 satisfy a preset reference.

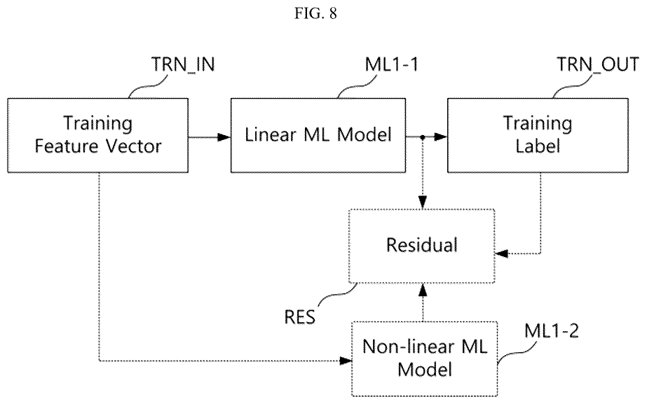

FIG. 5 is a flowchart illustrating a method for correcting a mask, which is performed in the apparatus for correcting the mask. The method for correcting the mask may be performed by the computing device 100 of FIG. 1. The method for correcting the mask will be described with reference to FIGS. 4 and 5.

In S110, the computing device 100 may receive the target design layout. According to some implementations, the computing device 100 may perform the OPC operation for the target design layout, to correspond to the target design layout, and may generate an initial mask layout. Alternatively, the computing device 100 may receive an initial mask layout together with the target design layout.

Referring to FIG. 4, the plurality of evaluation points EP1 and EP2 may be set at some positions of the circuit pattern of the mask layout MLO. The following description will be made with reference to FIG. 4, on the assumption that two evaluation points EP1 and EP2 are set for the circuit pattern of the mask layout MLO.

According to some implementations, the computing device 100 may set the gauges G1 and G2 to correspond to the evaluation points EP1 and EP2, respectively, and may set, as the target points TP1 and TP2, the points, which corresponds to the evaluation points EP1 and EP2, along the gauges G1 and G2 in the circuit pattern of the target design layout TLO.

In S120, the computing device 100 may infer the mask bias corresponding to the mask layout by inputting a feature vector into a first machine learning model. Regarding the feature vector and the mask bias, a plurality of feature vectors corresponding to the plurality of evaluation points EP1 and EP2 of FIG. 4 are input into the first machine learning model, and the plurality of mask biases MB1 and MB2 corresponding to the plurality of evaluation points EP1 and EP2 may be output from the first machine learning model.

In S130, the computing device 100 may generate the predicted pattern PPC based on the circuit pattern of the mask layout MLO and the mask biases MB1 and MB2 inferred.

The computing device 100 may generate the predicted pattern PPC based on the predicted points PP1 and PP2 positioned to be spaced apart from the evaluation points EP1 and EP2 by the mask biases MB1 and MB2. For example, for the Manhattan mask, the predicted pattern PPC may be generated by moving segments, in which the evaluation points EP1 and EP2 are positioned, in the mask layout by the mask biases MB1 and MB2, respectively. Each edge in the Manhattan mask may include a plurality of segments. For the curvilinear mask, the predicted points PP1 and PP2 may be determined by moving the evaluation points EP1 and EP2 by the mask biases MB1 and MB2, respectively, and the predicted pattern PPC may be generated in the form of a spline curve formed by linking the predicted points PP1 and PP2.

In S140, the computing device 100 may compare the predicted pattern PPC with the target design layout TLO, and may determine whether to correct the mask, based on the comparison result. Referring to FIG. 4, the predicted pattern PPC is compared with the circuit pattern of the target design layout, and the mask correction may be determined when the predicted edge placement errors (EPEs) EPEL and EPE2 are beyond a specific reference. For example, when the predicted EPEs EPEL and EPE2 are smaller than a preset value, that is, when the predicted EPEs EPE1 and EPE2 are smaller than a unit of a preset mask correction amount, the mask correction may be stopped. Otherwise, the mask correction may be determined to continue to be performed.

In S150, the computing device 100 may determine the mask correction amount based on the predicted EPEs EPE1 and EPE2. According to some implementations, the mask correction amount may be determined based on a table which is formed by mapping the size of the predicted EPE to the mask correction amount. According to other implementations, the mask correction amount may be determined, based on the EPE correlation with another evaluation point. For example, a ‘cross-meef’ (mask error enhancement factor) between evaluation points may be calculated, and the mask correction amount may be determined by performing the computation between the cross-meef and the predicted EPEs EPEL and EPE2.

When a mask correction amount is determined to correspond to each of the evaluation points EP1 and EP2, the computing device 100 may correct the mask layout MLO by changing positions of segments corresponding to the evaluation points EP1 and EP2, respectively, in the mask layout or position of the evaluation points EP1 and EP2. For example, for the Manhattan mask, the mask layout MLO may be corrected by moving each of segments, in which the evaluation points EP1 and EP2 are positioned, respectively, in the mask layout by a relevant mask correction amount. For the curvilinear mask, a corrected mask layout may be generated in the form of a spline curve formed by linking points, which are obtained by moving the evaluation points EP1 and EP2 by the relevant mask correction amounts.

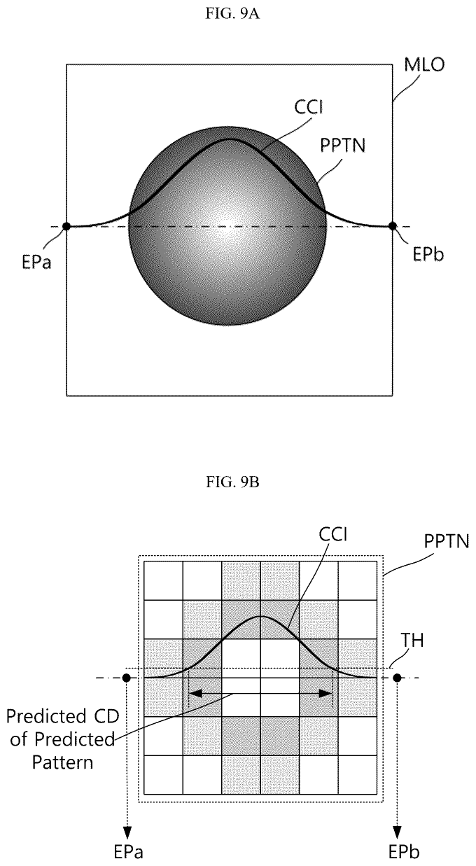

FIG. 6 is a view illustrating a first learning model (or first machine learning model) ML1 for inferring a mask bias. The first learning model ML1 may be used to infer the mask bias to perform the method for correcting the mask by the computing device 100 of FIG. 1.

Referring to FIG. 6, the first learning model ML1 may receive a feature vector FV1 at an evaluation point EP and may output a mask bias MB_O corresponding to the evaluation point EP.

The feature vector FV1 may include an optical feature, a geometrical feature, and a resist feature. Alternatively, the feature vector FV1 may include an optical feature vector, a geometrical feature vector, and a resist feature vector including the optical feature, the geometrical feature, and the resist feature, respectively. The computing device 100 may input, into the first machine learning model ML1, the feature vector FV1 having an optical feature value, a geometrical feature value, and a resist feature value, and corresponding to evaluation points (EPS), respectively. The first machine learning model ML1 may output a plurality of mask biases MB_O corresponding to a plurality of evaluation points, respectively, based on the feature vector FV1.

The first machine learning model ML1 may be a model trained using training data, which is obtained by labeling the feature vector having the optical feature value, the geometrical feature value, and the resist feature value with the edge placement error (EPE). The training of the first machine learning model ML1 using the training data may be performed by the computing device 100 or by an additional computing device. The edge placement error (EPE) may be measured on a sample wafer fabricated using the mask layout. For example, the feature vector calculated based on the mask layout may be labeled with the edge placement error (EPE) measured on the sample wafer fabricated using the mask layout. The edge placement error (EPE) may be measured based on the difference between the contour of a circuit pattern included in an ADI image of the sample wafer, or the contour of the circuit pattern included in an ACI image of the sample wafer, and the mask layout. The EPEs corresponding to the evaluation positions of the mask layout may be measured based on the contour of the circuit pattern included in the ADI image, or the contour of the circuit pattern included in the ACI image. The ADI image may be an image of a sample wafer after the development process of the photolithography process is finished, and the ACI image may be an image of a sample wafer after the etching process is finished.

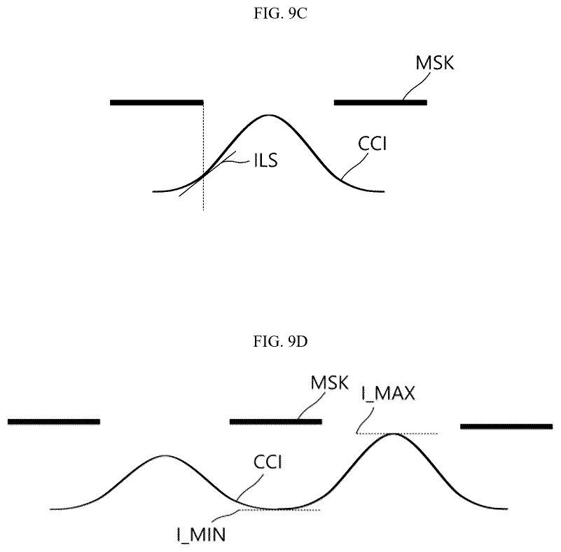

According to some implementations, the edge placement error (EPE) may be a measurement critical dimension (CD) MCD. Referring to FIG. 7, the measurement critical dimension MCD of the ACI image of the sample wafer or of the ADI image of the sample wafer, and a size MSK_SZ of the circuit pattern corresponding to the mask layout may determine the difference by a mask bias MB_L from a left edge of the circuit pattern and a mask bias MB_R from a right edge of the circuit pattern. In this case, the feature vector of the training data may be labeled with a value ((MB_L+MB_R)/2=|MSK_SZ-MCD|/2) corresponding to half the difference between the measurement critical dimension MCD and the size MSK_SZ of the circuit pattern corresponding to the mask layout.

According to some implementations, the labeling of the feature vector of the training data may be performed further based on a misalignment of the mask layout. For example, the value of the mask bias MB_L from the left edge and the value of the mask bias MB_R from the right edge may be exactly measured, based on a misalignment degree MIS_ALIGN of the mask layout. The feature vector corresponding to a left evaluation point EP_L may be labeled with the mask bias MB_L from the left edge, and the feature vector corresponding to a right evaluation point EP_R may be labeled with the mask bias MB_R from the right edge. The misalignment degree MIS_ALIGN may refer to the difference between the center MSK_CEN of the circuit pattern of the mask layout and the center critical dimension_CEN of the measurement critical dimension of the sample wafer. According to implementations, the misalignment degree MIS_ALGN of the mask layout may be inferred by using the additional learning model. In this case, training data for inferring the misalignment degree of the mask layout may be obtained by labeling the feature vector, which includes the optical feature, the geometrical feature, and the resist feature at each evaluation point, with a value corresponding to the half the difference (|MB_L−MB_R|) between the mask bias MB_L from the left edge of the mask layout and the mask bias MB_R from the right edge.

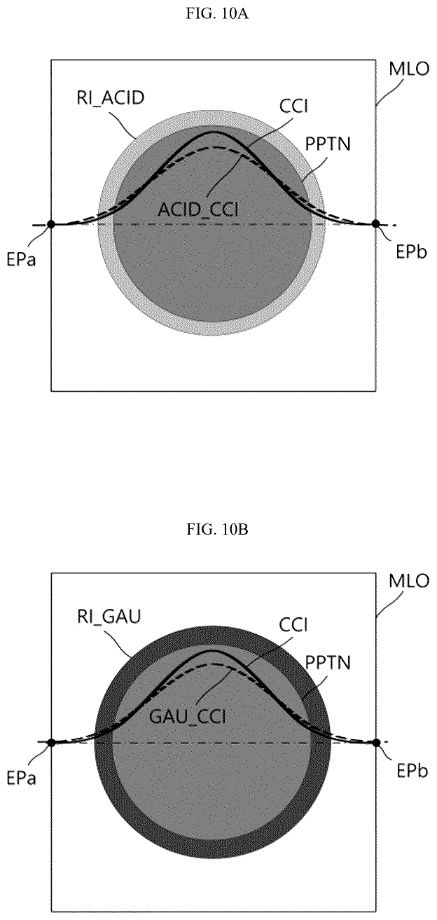

FIG. 8 is a view illustrating a first machine learning model according to some implementations. The first machine learning model to be described with reference to FIG. 8, may correspond to the first machine learning model ML1 of FIG. 7.

According to some implementations, the first machine learning model ML1 may include a (1-1)-th machine learning model ML1-1 for inferring a mask bias and a (1-2)-th machine learning model ML1-2 for inferring a residual difference of the inferred mask bias.

The (1-1)-th machine learning model ML1-1 may be the same as the first machine learning model ML1 described with reference to FIG. 6. For example, referring to FIGS. 4 and 8, the (1-1)-th machine learning model ML1-1 may be a machine learning model trained such that a training feature vector TRN_IN including an optical feature value, a geometrical feature value, and a resist feature value corresponding to the evaluation point EP infers the mask biases MB1 and MB2 which are training data labels TRN_OUT.

The (1-2)-th machine learning model ML1-2 may be trained using training data obtained by labeling a feature vector with the residual difference of the mask bias inferred. The residual difference RES of the mask bias inferred may be the difference between the predicted pattern based on the mask bias, which is inferred by the (1-1)-th machine learning model ML1-1, and the target layout. Referring to FIGS. 4 and 8, the (1-2)-th machine learning model ML1-2 may be trained using training data labeled with the measurement (EPEs) EPE1 and EPE2, which is the difference between the predicted pattern (PPC) based on the mask biases MB1 and MB2 inferred by the (1-1)-th machine learning model ML1-1 and the circuit pattern TLO of the target layout. In other words, the (1-2)-th machine learning model ML1-2 may receive the training feature vector TRN_IN including the optical feature value, the geometrical feature value, and the resist feature value and may be trained to infer the measurement EPEs (EPE1 and EPE2) which is the residual difference RES.

According to some implementations, the (1-1)-th machine learning model ML1-1 for inferring the mask bias may be a machine learning model based on linear regression, and the (1-2)-th machine learning model ML1-2 for inferring the residual difference of the mask bias may be a machine learning model based on a non-linearity. For example, the (1-1)-th machine learning model ML1-1 may be a linear regression model, and the (1-2)-th machine learning model ML1-2 may be any one of a decision tree model or a random forest model. In this case, the computing device 100 may more accurately infer the mask bias because the (1-1)-th machine learning model ML1-1 and the (1-2)-th machine learning model ML1-2 have different characteristics.

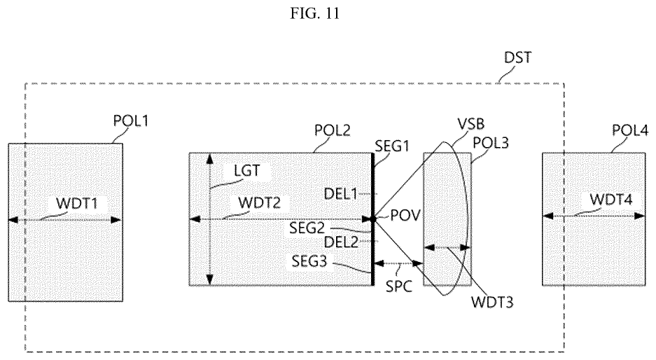

FIGS. 9A to 9D are views illustrating optical feature vectors of feature vectors. The feature vectors to be described with reference to FIGS. 9A to 9D may correspond to the feature vector FV1 of the first machine learning model ML1 of FIG. 6 or may correspond to at least any one of training feature vectors TRN_IN of the (1-1)-th machine learning model ML1-1 and the (1-2)-th machine learning model ML1-2 of FIG. 8.

FIG. 9A illustrates a pattern PPTN predicted based on the circuit pattern of the mask layout MLO in an aerial image (AI).

The aerial image (AI) is the distribution of light intensity expressed as a function of a spatial position through the mask on the wafer. The optical attributes (for example, a light source, a mask, and other optical attributes) of a photolithography device are used to determine the aerial image. Accordingly, the aerial image may be formed based on the mask layout through a simulation of the photolithography process. For example, the computing device 100 may generate an aerial image by applying an optical model, which is called an optic model (which may be a convolution filter) obtained by simulating the optical attributes of the photolithography device, to the mask layout.

Points inside a predicted pattern PPTN of the aerial image may have mutually different intensities. For example, referring to FIG. 9A, regarding the intensity of the predicted pattern PPTN, the value of a cross cut intensity plot CCI passing through evaluation points EPa and EPb and viewed in a cross-cut view perpendicular to a plane of the aerial image (AI), may vary between the evaluation points EPa and EPb.

FIG. 9B is a view illustrating the predicted pattern PPTN and the cross cut intensity plot CCI of the aerial image of FIG. 9A, in view of image pixels. According to some implementations, the computing device 100 may determine, as a predicted critical dimension of the predicted pattern PPTN, a portion in which the value of the cross-cut intensity plot CCI, which varies between the evaluation points EPa and EPb, is equal to or greater than a preset threshold TH.

Referring to FIG. 9C, the computing device 100 may use, as one of optical features, a normalized image log-slope (ILS) at a point corresponding to the edge of the predicted critical dimension in the cross-cut intensity plot CCI. The image log-slope ILS may be calculated to correspond to each of the evaluation points EPa and EPb. The image log-slope ILS may be calculated based on following Equation 1.

$$I L S = Image Log Slope = \frac{\partial ln ( I )}{\partial x} = \frac{1}{I} \frac{\partial I}{\partial x} \qquad Equation 1$$

Referring to FIG. 9D, the computing device 100 may use, as some of the optical features, the maximum intensity value I_MAX and the minimum intensity value I_MIN in the cross-cut intensity plot CCI. Alternatively, the ratio of the minimum intensity value I_MIN to the maximum intensity value I_MAX may be used as one of the optical features. Alternatively, the image contrast based on following Equation 2 may be used as one of the optical features. Each of the optical features corresponding to the evaluation points EPa and EPb may be calculated.

$$Image Contrast = \frac{{I}_{m ax} - {I}_{m i n}}{{I}_{m ax} + {I}_{m i n}} \qquad Equation 2$$

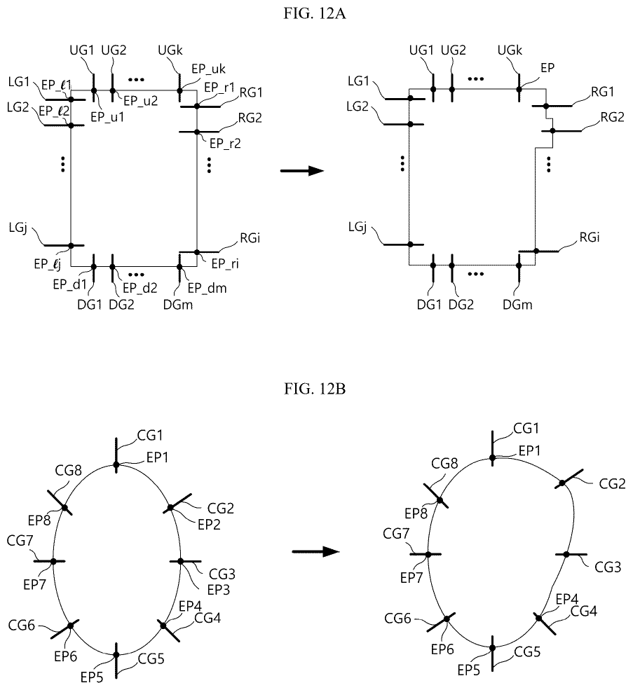

FIGS. 10A to 10B are views illustrating a resist feature vector of feature vectors. The feature vectors to be described with reference to FIGS. 10A to 10B may correspond to the feature vector FV1 of the first machine learning model ML1 of FIG. 6 or may correspond to at least any one of training feature vectors TRN_IN of the (1-1)-th machine learning model ML1-1 or the (1-2)-th machine learning model ML1-2 of FIG. 8.

FIGS. 10A and 10B illustrate results RI_ACID and RI_GAU obtained by applying a resist model to the pattern PPTN predicted based on the circuit pattern of the mask layout MLO in a resist image (RI).

The resist layer on the wafer is exposed, and the aerial image is transferred to the resist layer. The result obtained by transferring the aerial image to the resist layer may be called the resist image RI. The resist image RI may be defined as an available spatial distribution of the resist at the resist layer. To calculate the resist image from the aerial image, the resist model may be used. The resist model may be related only to the attributes (for example, effects of chemical processes, which are produced in exposing, PEB, and developing processes) of the resist layer. The resist model may be a model obtained by simulating acid-Quencher reaction of the photoresist, based on the attributes of the preset resist layer. For example, the computing device 100 may generate the resist image RI by applying the resist kernel (for example, an ACID kernel, a BASE kernel, or a Gaussian kernel) to the aerial image. Alternatively, the resist model may be a model obtained by simulating the reaction of the photoresist to light of the extreme ultra violet wavelength range (EUV), based on the attributes at the preset resist layer. In addition to the resist model based on the kernel or the filter, the computing device 100 may generate a resist image using a resist model employing a rigorous modeling scheme for partially simulating the variation depending on the PEB process and the developing process.

Referring to FIGS. 10A and 10B, the computing device 100 may use, as some of resist features, intensity values corresponding to the evaluation points EPa and EPb in a cross cut intensity plot ACID_CCI or GAU_CCI viewed in a cross-cut view passing through the evaluation points EPa and EPb of the resist image RI and perpendicular to a plane of the resist image RI.

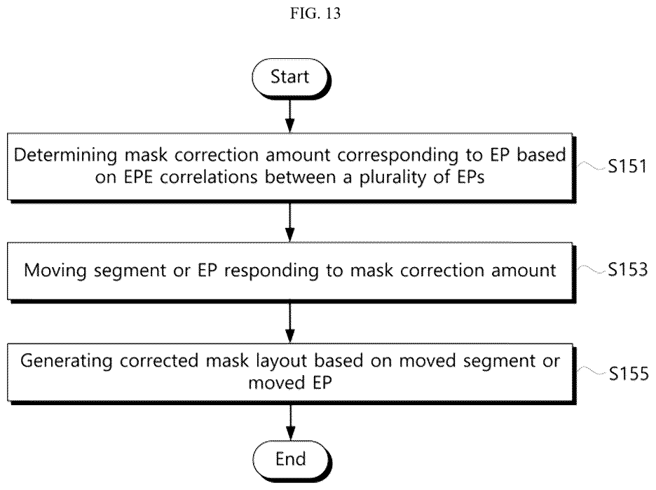

FIG. 11 is a view illustrating a geometrical feature vector of a feature vector. The feature vector to be described with reference to FIG. 11 may correspond to the feature vector FV1 of the first machine learning model ML1 of FIG. 6 or may correspond to at least any one of training feature vectors TRN_IN of the (1-1)-th machine learning model ML1-1 or the (1-2)-th machine learning model ML1-2 of FIG. 8.

FIG. 11 illustrates circuit patterns POL1, POL2, POL3, and POL4 of the mask layout. The circuit patterns POL1, POL2, POL3, and POL4 may be referred to as “polygons”.

The computing device 100 may calculate, as a geometrical feature vector, geometrical characteristics of at least one polygon related to a point of view (POV). The point of view (POV) may correspond to an evaluation point. The geometrical characteristics may include a shape, a density, a length, a distance, or a hierarchical structure.

The geometrical feature of the polygon will be described with reference to FIG. 11, by way of example.

Referring to FIG. 11, the geometrical characteristics corresponding to the polygons POL1, POL2, POL3, and POL4 within a preset range DST from the view of point POV may be calculated in the form of the geometrical feature vector. For example, the length LGT of the edge of the polygon POL2 positioned at the point of view POV, or the length of the segment SEG1 may be included in the geometrical feature. Each of the edges of the polygons POL1, POL2, POL3, and POL4 may include a plurality of segments. For example, the edge of the polygon POL2 having the point of view POV may include a plurality segments SEG1, SEG2, and SEG3 divided by virtual dividers DEL1 and DEL2, and the point of view POV may be positioned at the segment SEG2 which is any one of the segments SEG1, SEG2, and SEG3.

Hereinafter, other geometrical features will be described.

The distance to the polygon, which is adjacent to the segment having the point of view POV in a direction perpendicular to the segment, from the segment may be included in the geometrical feature. For example, the distance SPC to the polygon POL3, which is adjacent to the segment SEG2 having the point of view POV in a direction perpendicular to the segment SEG2, from the segment SEG2 may be included in the geometrical feature.

Lengths of polygons perpendicular to the edge having the point of view POV may be included in the geometrical feature. For example, when the edge having the point of view POV is an edge provided in the vertical direction, at least one of horizontal width WDT1 of the polygon POL1, horizontal width WDT2 of the polygon POL2, horizontal width WDT3 of the polygon POL3, or horizontal width WDT4 of the polygon POL4 may be included in the geometrical feature.

The area of the polygon POL2 having the point of view POV may be included in the geometrical feature.

The presence of a pattern under the point of view POV may be included in the geometrical feature.

The pattern density within the preset range DST from the point of view POV may be included in the geometrical feature. For example, the areas of the polygons, which are within the range DST, in relation to the area of the range DST may be included in the geometrical feature.

The spatial area and the pattern area within a preset visible range VSB from the point of view POV may be included in the geometrical feature. For example, the area corresponding to the visible range VSB in the polygon POL3, and the area of a space, which is not occupied by the polygons, in the visible range VSB may be included in the geometrical feature. Although the following description will be made with reference FIG. 11 on the assumption that the visible range VSB has the shape of a fan, the visible range VSB may have another shape.

The computing device 100 may involve another feature into the feature vector, in addition to the feature described with reference to FIGS. 9A to 9D, FIGS. 10A and 10B, and FIG. 11.

For example, the position (up, down, right, or left) of the segment SEG2 having the point of view POV in the polygon may be included, as the geometrical feature, in the feature vector. Alternatively, the lengths of the segments SEG1 and SEG3 adjacent to the segment SEG2 having the point of view POV and the length of the polygon in the direction perpendicular to the segment may be included in the feature vector.

Although FIG. 11 illustrates the geometrical features based on the patterns of the Manhattan mask, the geometrical features may be calculated from the patterns of the curvilinear mask which is similar to the Manhattan mask.

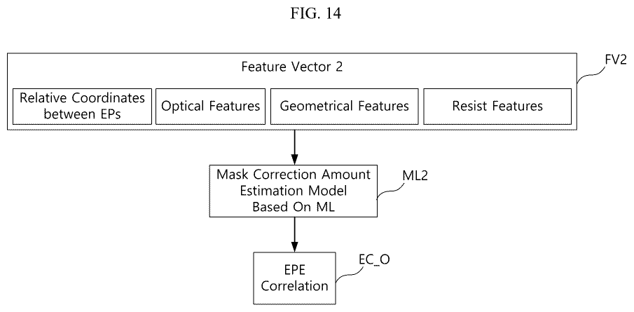

FIGS. 12A and 12B are views to describe mask correction of the Manhattan mask and the curvilinear mask. The Manhattan mask and the curvilinear mask described with reference to FIGS. 12A and 12B may correspond to the mask of FIG. 1.

Referring to FIG. 12A, the computing device 100 may correct the Manhattan mask by moving each of segments of the Manhattan mask by a mask correction amount corresponding to each segment. For example, the Manhattan mask of FIG. 12A may include segments corresponding to a plurality of evaluation points EP_r1 to EP_ri, EP_l1 to EP_lj, EP_d1 to EP_dm, and EP_u1 to EPuk, and the gauges RG1 to RGi, LG1 to LGj, DG1 to DGm, and UG1 to UGk. The computing device 100 may move each of the segments corresponding to a plurality of evaluation points EP_r1 to EP_ri, EP_lJ to EP_lj, EP_d1 to EP_dm, and EP_u1 to EP_uk, and the gauges RG1 to RGi, LG1 to LGj, DG1 to DGm, and UG1 to UGk by a mask correction amount corresponding to each segment. The segments may be moved along relevant gauges. For example. FIG. 12A illustrates that segments corresponding to two gauges RG1 and RG2 in the Manhattan mask are moved by the mask correction amounts corresponding to the segments. It may be recognized that the mask correction amount of the segment corresponding to the gauge RG2 is different from the mask correction amount of the segment corresponding to the gauge RG1.

Referring to FIG. 12B, the computing device 100 may correct the curvilinear mask by moving each of the evaluation points EP1 to EP8 of the curvilinear mask by a relevant mask correction amount. For example, the computing device 100 of FIG. 12B may move each of the evaluation points EP1 to EP8 of the curvilinear mask along a relevant one of the gauges CG1 to CG8 by a relevant mask correction amount. FIG. 12B illustrates that each of two evaluation points CG2 and CG3 are moved by a relevant mask correction amount. The computing device 100 may generate the corrected mask by generating a spline curve linking moved evaluation points to each other.

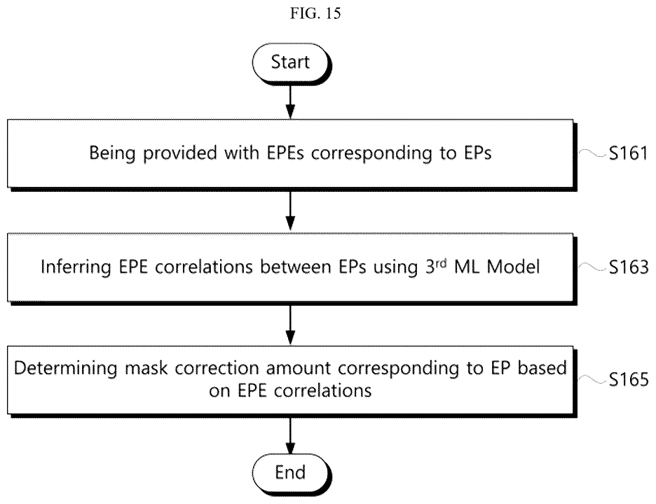

FIG. 13 is a flowchart illustrating a method for correcting a mask, based on EPE correlation. The method for correcting the mask, based on the EPE correlation may be used in correcting the mask, which is performed by the computing device 100 of FIG. 1. The method for correcting the mask based on the EPE correlation will be described with reference to FIGS. 1, 4, and 13.

In S151, the computing device 100 may determine a mask correction amount corresponding to each evaluation point EP, based on the EPE correlation between the plurality of evaluation points (EPs). For example, the computing device 100 may calculate the “cross-meef” between evaluation points and may perform a computation with respect to the “cross-meef” and the predicted EPE to determine the mask correction amount.

For example, the computing device 100 may receive a predicted edge placement error (EPE) corresponding to each of a plurality of evaluation points on a sample wafer fabricated using a mask based on the mask layout. The predicted EPE may be a predicted EPE described with reference to FIG. 4. The predicted EPE may be a difference between a predicted pattern and a pattern of a target design layout. In other words, referring to FIG. 4, the predicted EPE may be the distance between the evaluation points EP1 to EP2 of the predicted pattern PPC and the target point TP1 to TP2 positioned in the pattern of the target design layout TLO corresponding to the evaluation points EP1 to EP2.

The computing device 100 may infer the EPE correlation between the plurality of evaluation points by using the second machine learning model. According to some implementations, the EPE correlation may be an EPE correlation matrix having, as an element, the “cross-meef” which is the EPE correlation between the two evaluation points of the plurality of evaluation points. For example, the EPE correlation matrix corresponding to N evaluation points may be expressed as Equation 3.

$$A = [ \begin{matrix}{m}_{11} & {m}_{12} & ⋯ & {m}_{NN} \\ {m}_{21} & {m}_{22} & ⋯ & {m}_{2 N} \\ ⋮ & ⋮ & ⋱ & ⋮ \\ {m}_{N 1} & {m}_{N 2} & ⋯ & {m}_{NN}\end{matrix} ] \qquad Equation 3$$

In Equation 3, ‘mᵢⱼ’ refers to the ‘cross-meef’ between the evaluation point ‘i’ and the evaluation point ‘j’. The ‘cross-meef’ between the evaluation point ‘i’ and the evaluation point ‘j’ may be inferred through the second machine learning model which receives at least one of the optical feature value, the geometrical feature value, or the resist feature value of the evaluation point ‘j’ and the relative coordinates of the evaluation point ‘j’ for the evaluation point ‘i’.

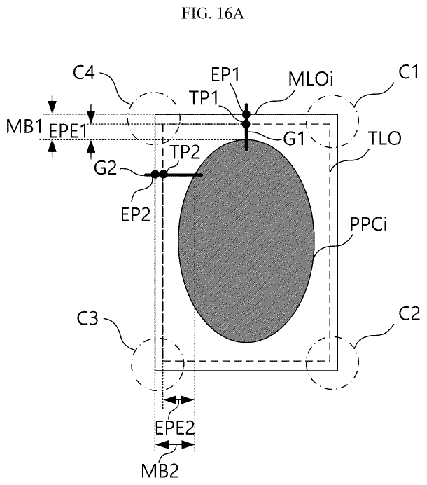

Referring to FIG. 14, the second machine learning model ML2 may output an EPE correlation EC_O of each evaluation point by receiving the feature vector FV2 including at least one of an optical feature value, a geometrical feature value, or a resist feature value of each evaluation point, and relative coordinates between the plurality of evaluation points. The second machine learning model ML2 may be trained by using data obtained by labeling the feature vector with an EPE variation degree of another evaluation point for the movement of any one evaluation point of the plurality of evaluation points. For example, the training data may be obtained by labeling a feature vector including at least one of the optical feature value, the geometrical feature value, or the resist feature value of an evaluation point ‘j’ and the relative coordinates of the evaluation point ‘j’ for an evaluation point ‘i’, with the partial derivative expression∂EPEᵢ/∂Mⱼ. In other words, the feature vector may be labeled with a predicted variation EPEi of the evaluation point ‘i’ to the movement amount ‘Mj’ of the evaluation point ‘j’.

According to some implementations, the computing device 100 may determine a mask correction amount corresponding to each evaluation point, based on the EPE correlation matrix and the following Equation 4.

$$Δ mask = - {η ( {A}^{T} A )}^{- 1} \cdot {A}^{T} \cdot E P E \qquad Equation 4$$

In Equation 4, Δmask may refer to a mask correction amount corresponding to each of evaluation points, ‘A’ may refer to an EPE correlation matrix of Equation 3, and EPE may be a predicted EPE described above. η may be a damping parameter having a value of ‘1’ or less, which is preset, to adjust the mask correction amount, for the convergence of the mask correction amount.

Referring back to FIG. 13, in S153, the computing device 100 may correct the mask based on the determined mask correction amount. For example, the computing device 100 may move a segment corresponding to each evaluation point of the Manhattan mask or may move each evaluation point of the curvilinear mask.

In S155, the computing device 100 may generate the corrected mask based on the moved segment or the moved evaluation point. For example, the mask linking the moved segments to each other may be generated as a corrected Manhattan mask, or the spline curve linking the moved evaluation points to each other may be generated as a corrected curvilinear mask.

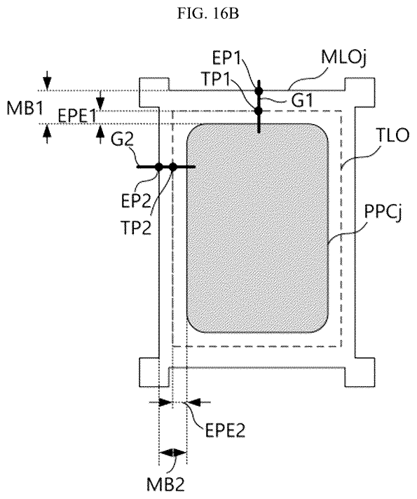

FIG. 15 is a view illustrating a method for determining a mask correction amount. The method for determining the mask correction amount the mask, based on the EPE correlation may be used in correcting the mask, which is performed by the computing device 100 of FIG. 1.

In S161, the computing device 100 may receive the predicted EPE corresponding to the evaluation points (EPs) of the mask layout. The predicted EPE may be a predicted EPE described with reference to FIG. 4. The predicted EPE may be a difference between a predicted pattern and a pattern of a target design layout.

In S163, the computing device 100 may infer the EPE correlation between the evaluation point EPs based on a third machine learning model. The third machine learning model may be the same as the second machine learning model described with reference to FIG. 14. The EPE correlation may be inferred as an EPE correlation matrix of Equation 3 using the third machine learning model.

In S165, the computing device 100 may determine a mask correction amount corresponding to each of the evaluation points (EPs), based on the EPE correlation matrix and Equation 4.

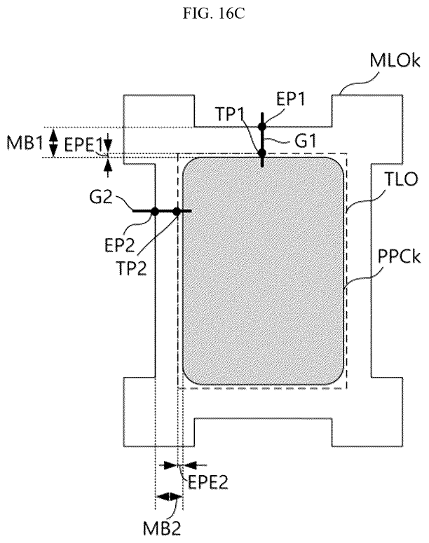

FIG. 16A illustrates an initial mask layout MLOi, FIG. 16B illustrates a mask layout MLOj during the correction process of the initial mask layout MLOi, and FIG. 16C illustrates a mask layout MLOk after the correction of the initial mask layout MLOi is finished. The process of correcting the initial mask layout MLOi of FIGS. 16A, 16B, and 16C may be performed by the computing device 100 of FIG. 1. The following description will be made on the assumption that the mask of FIGS. 16A, 16B, and 16C may be the Manhattan mask. Although the following description is made with reference to FIGS. 16A, 16B, and 16C, in that two evaluation points are provided, may more evaluation points may be provided.

Referring to FIG. 16A, the computing device 100 may generate an intermediate mask layout MLOj by correcting the initial mask layout MLOi.

The computing device 100 may infer a plurality of mask biases MB1 and MB2 by inputting feature vectors corresponding to the plurality of evaluation points EP1 and EP2 of the initial mask layout MLOi into the first machine learning model described with reference to FIG. 6. The computing device 100 may generate a predicted pattern PPCi based on the initial mask layout MLOi and the mask biases MB1 and MB2. The computing device 100 may determine the predicted EPE1 and EPE2 based on the predicted pattern PPCi and the target design layout TLO. According to some implementations, the predicted EPE may be an EPE correlation matrix based on Equation 3. The computing device 100 may infer the EPE correlation matrix using the second machine learning model described with reference to FIG. 14. The computing device 100 may determine a mask correction amount corresponding to the plurality of evaluation points EP1 and EP2, based on the EPE correlation matrix and Equation 4. The computing device 100 may move a plurality of segments constituting the initial mask layout MLOi to correspond to the mask correction amount.

The intermediate mask layout MLOj is a mask layout generated based on the result made by moving each segment of the initial mask layout MLOi. It may be recognized that the hammer shape of the mask layer is added, as segments of corners C1 to C4 of the initial mask layout MLOi are moved.

Referring to FIG. 16B, the computing device 100 may infer mask biases MB1 and MB2, predicted patterns PPCj, and predicted EPEL and EPE2 with respect to the intermediate mask layout MLOj, which is similar to the process for the initial mask layout MLOi. The computing device 100 may determine a mask correction amount corresponding to the plurality of evaluation points EP1 and EP2 and may correct the intermediate mask layout MLOj to determine a final mask layout MLOk of FIG. 16C.

Referring to FIG. 16C, the computing device 100 may infer mask biases MB1 and MB2, a predicted pattern PPCk, and predicted (EPEs) EPE1 and EPE2 with respect to the final mask layout MLOk, which is similar to the process performed for the initial mask layout MLOi. The computing device 100 may stop the mask correction, when the predicted EPEs EPE1 and EPE2 are within a preset reference. The expanded shape of the hammer of the intermediate mask layout MLOj may be recognized in the final mask layout MLOk.

In addition, it may be recognized that the predicted EPEs EPE1 and EPE2 are reduced at each stage in an order from the initial mask layout MLOi, to the intermediate mask layout MLOj, and to the final mask layout MLOk, where the predicted EPEs EPE1 and EPE2 are smaller than a preset value.

As described above, in the apparatus and the method for correcting the mask of the present disclosure, the intended circuit pattern may be more precisely formed on the wafer.

According to the apparatus and the method for correcting the mask of the present disclosure, the mask used in the process for fabricating the semiconductor device may be rapidly corrected.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The above description refers to detailed implementations for carrying out the present disclosure. Implementations in which a design is changed simply or which are easily changed may be included in the present disclosure as well as an implementation described above. In addition, technologies that are easily changed and implemented by using the above implementations may be included in the present disclosure. Accordingly, the scope of the present disclosure is not limited to the above-described implementations, but defined by following claims and equivalents thereof.

While the present disclosure has been described with reference to implementations thereof, it will be apparent to those of ordinary skill in the art that various changes and modifications may be made thereto without departing from the spirit and scope of the present disclosure as set forth in the following claims.

What is claimed is:

1. A method for correcting a photomask, the method comprising:
receiving a target design layout of a semiconductor device;
inferring, by at least one processor, a mask bias by inputting an optical feature value, a geometrical feature value, and a resist feature value of a mask layout based on the target design layout, into a first machine learning model;
generating, by the at least one processor, a predicted pattern by incorporating the mask bias in the mask layout;
comparing, by the at least one processor, the predicted pattern with the target design layout; and
correcting, by the at least one processor, the mask layout based on a result of the comparison between the predicted pattern and the target design layout.

2. The method of claim 1, wherein the target design layout is based on at least one of an after-cleaning inspection design layout or an after-develop inspection design layout.

3. The method of claim 1, wherein the mask layout includes at least one of a rectilinear pattern or a curvilinear pattern.

4. The method of claim 3, further comprising:
inferring, by the at least one processor, the mask bias corresponding to an evaluation point of the mask layout; and
generating, by the at least one processor, the predicted pattern by changing a position of a segment corresponding to the evaluation point of the rectilinear pattern or a position of the evaluation point of the curvilinear pattern, based on the mask bias.

5. The method of claim 4, further comprising:
determining, by the at least one processor, a mask correction amount corresponding to the evaluation point, based on a correlation of an edge placement error between a plurality of evaluation points;
changing, by the at least one processor, the position of the segment corresponding to the evaluation point of the rectilinear pattern or the position of the evaluation point of the curvilinear pattern, to correspond to the mask bias; and
generating, by the at least one processor, a corrected mask layout, based on the segment or the evaluation point having the position changed.

6. The method of claim 5, wherein the correlation of the edge placement error includes:
a change in an edge placement error of a second evaluation point resulting from a change in the position of a first evaluation point, and
wherein the plurality of evaluation points include the first evaluation point and the second evaluation point.

7. The method of claim 5, further comprising:
calculating, by the at least one processor, the edge placement error corresponding to the evaluation point, based on the target design layout, the mask layout, and the mask bias; and
inferring, by the at least one processor, the correlation of the edge placement error between the plurality of evaluation points using a second machine learning model.

8. The method of claim 7, wherein the second machine learning model is trained using data obtained by labeling a feature vector, which includes at least one of the optical feature value, the geometrical feature value, or the resist feature value corresponding to a first evaluation point, and relative coordinates between the first evaluation point and a second evaluation point, with an edge placement error variation degree of the second evaluation point for movement of the first evaluation point.

9. The method of claim 1, wherein inferring of the mask bias includes:
inputting a feature vector including the optical feature value, the geometrical feature value, and the resist feature value, in form of a numerical value, into the first machine learning model.

10. The method of claim 9, wherein the optical feature value corresponds to an evaluation point of the mask layout, is calculated from an aerial image based on the mask layout, and includes at least one of a maximum intensity value or a minimum intensity value of an image log-slope at the evaluation point.

11. The method of claim 9, wherein the resist feature value corresponds to an evaluation point of the mask layout, is calculated from a resist image based on the mask layout, and is based on an acid-quencher reaction of a photoresist at the evaluation point.

12. The method of claim 9, wherein the resist feature value corresponds to an evaluation point of the mask layout, is calculated from a resist image based on the mask layout, and is based on a reaction of photoresist to light of an extreme ultraviolet wavelength at the evaluation point.

13. The method of claim 1, wherein the first machine learning model includes:
a second machine learning model to receive a feature vector including at least one of the optical feature value, the geometrical feature value, or the resist feature value and based on linear regression for inferring a first mask bias; and
a third machine learning model based on non-linearity for inferring a residual difference of the first mask bias.

14. The method of claim 13, wherein the residual difference is a difference between the predicted pattern based on the first mask bias, and the target design layout.

15. A method for generating a photomask correction model, the method comprising:
receiving a mask layout of a semiconductor device;
receiving measurement data of a wafer fabricated using a mask based on the mask layout; and
training, by at least one processor, a first machine learning model using training data obtained by labeling an optical feature value, a geometrical feature value, and a resist feature value of the mask layout with a mask bias based on the measurement data.

16. The method of claim 15, wherein the measurement data is data measured based on a wafer obtained after a photolithography process is finished or measured based on a wafer after an etching process is finished.

17. The method of claim 15, wherein the mask bias is based on at least one of the mask layout, a measurement edge placement error measured on the wafer, or a measurement critical dimension.

18. The method of claim 17, wherein the mask bias is based on a distance between at least one of a pattern contour of an after develop inspection image of the wafer or a pattern contour of an after cleaning inspection image and an evaluation point of the mask layout, or based on a difference between the measurement critical dimension and a size of the mask layout.

19. A method for determining a photomask correction amount, the method comprising:
receiving an edge placement error corresponding to each of a plurality of evaluation points on a wafer fabricated using a mask based on a mask layout of a semiconductor device;
inferring, by at least one processor, edge placement error correlation between the plurality of evaluation points using a machine learning model; and
determining, by the at least one processor, the photomask correction amount of the mask layout, based on the edge placement error correlation and an edge placement error corresponding to each of the plurality of evaluation points,
wherein the machine learning model is trained:
using data obtained by labeling a feature vector including at least one of an optical feature value, a geometrical feature value, or a resist feature value corresponding to each of the plurality of evaluation points, and relative coordinates between the plurality of evaluation points, with an edge placement error variation degree of one evaluation point for movement of another evaluation point of the plurality of evaluation points.

20. The method of claim 19, further comprising:
adjusting, by the at least one processor, the photomask correction amount of the mask layout, based on a preset damping parameter,
wherein the preset damping parameter decreases a size of at least one of the photomask correction amount corresponding to each of the plurality of evaluation points.
